(19) United States
(12) Patent Application Publication
(10) Pub. No.: US 2026/0324497 A1
(43) Pub. Date: Oct. 15, 2026

(54) SEMICONDUCTOR PACKAGE STRUCTURE WITH STIFFENER MOLD AND METHOD OF FORMING THE SAME

(71) Applicant: Taiwan Semiconductor Manufacturing Company, Ltd., Hsinchu (TW)

(72) Inventors: Chieh-Ming CHANG, New Taipei City (TW); Ming-Chih YEW, Hsinchu City (TW); Kuo-Chin CHANG, Chiayi City (TW); Kathy Wei YAN, Hsinchu (TW); Chen-Shien CHEN, Zhubei City Hsinchu County (TW)

(73) Assignee: Taiwan Semiconductor Manufacturing Company, Ltd., Hsinchu (TW)

(21) Appl. No.: 19/174,151

(22) Filed: Apr. 9, 2025

(51) Int. Cl. H01L 23/24; H01L 21/48; H01L 23/00; H01L 23/538; H01L 25/065; H01L 25/18; H10B 80/00; H10D 80/30

(52) U.S. Cl. CPC H10W 76/47; H10W 42/121; H10W 70/099; H10B 80/00; H10D 80/30; H10W 70/611; H10W 70/65; H10W 72/0198; H10W 74/15; H10W 90/00; H10W 90/401; H10W 90/724; H10W 90/733; H10W 90/734

(57) ABSTRACT

A semiconductor package structure and a method of forming the same are provided. The semiconductor package structure includes a package substrate, a semiconductor device mounted over the package substrate, and a stiffener ring attached to the package substrate and surrounding the semiconductor device. The semiconductor package structure also includes a stiffener mold formed over the package substrate and covering the stiffener ring, wherein the coefficient of thermal expansion (CTE) of the stiffener mold is greater than the CTE of the stiffener ring. In addition, the stiffener mold is spaced apart from the semiconductor device.

### BACKGROUND

Semiconductor integrated circuits (ICs) are incorporated into many electronic devices. IC packaging has evolved in such a way that multiple ICs can be vertically stacked in so-called three-dimensional (3D) packages in order to save horizontal area on a printed circuit board (PCB). An alternative packaging technique, referred to as a 2.5D package, may use an interposer to couple one or more dies to a substrate. A plurality of IC chips, which may be of heterogeneous technologies, are mounted on the interposer. Connections among the various ICs are routed through conductive patterns in the interposer. These interposer and stacked IC packaging techniques are called 2.5D-IC and 3D-IC, respectively.

Although existing package structures and methods for fabricating package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1I are schematic views of intermediate steps of forming a semiconductor package structure including a stiffener mold covering a stiffener ring, in accordance with some embodiments.

FIGS. 2A to 2C illustrate cross-sectional views of semiconductor package structures having stiffener molds of different configurations, in accordance with some embodiments.

FIG. 3 illustrate a cross-sectional view of a semiconductor package structure having a stiffener mold composed of a plurality of sub-molds, in accordance with some embodiments.

FIGS. 4A and 4B illustrate cross-sectional views of semiconductor package structures having stiffener molds with uneven thickness, in accordance with some embodiments.

FIGS. 5A and 5B are schematic views of a semiconductor package structure having a stiffener mold with uneven thickness, in accordance with some embodiments.

FIG. 6 illustrate a plan view of a semiconductor package structure having a stiffener mold covering only the corner areas of the stiffener ring, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The structure may be otherwise oriented (rotated 90 degrees or at other orientations) and the spatially relative descriptors used herein may likewise be interpreted accordingly.

A semiconductor package structure and the method for forming the same are provided in accordance with various embodiments. The semiconductor package structure includes a package substrate, a semiconductor device mounted on the package substrate, a stiffener ring attached to the package substrate and surrounding the semiconductor device, and a stiffener mold covering the stiffener ring. In some embodiments, the stiffener mold has a larger thermal expansion coefficient (CTE) than the stiffener ring, which improves package warpage control. Further, due to the presence of the stiffener mold, a smaller stiffener ring can also be used, which helps reduce internal stress issues caused by the larger modulus of the stiffener ring. Additionally, the stiffener mold is spaced apart from the semiconductor device (i.e., they are not in contact), thereby preventing additional stress on the semiconductor device and additional interface delamination issues. Accordingly, the reliability of the semiconductor package structure is improved.

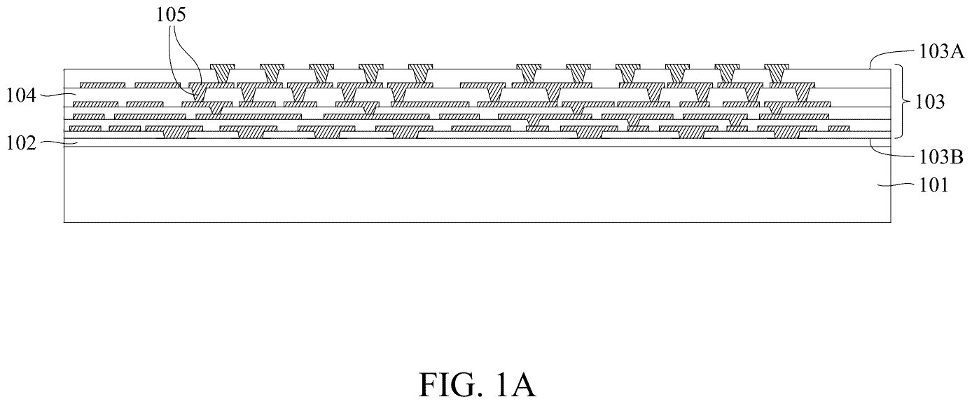

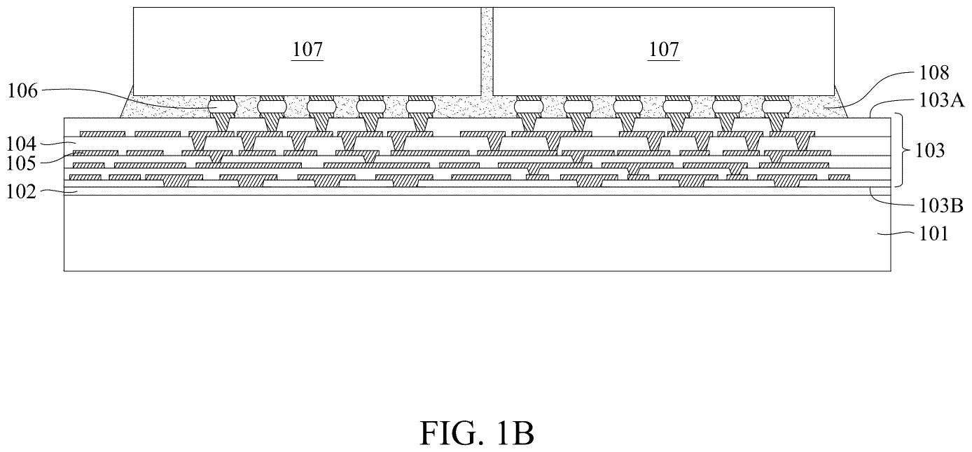

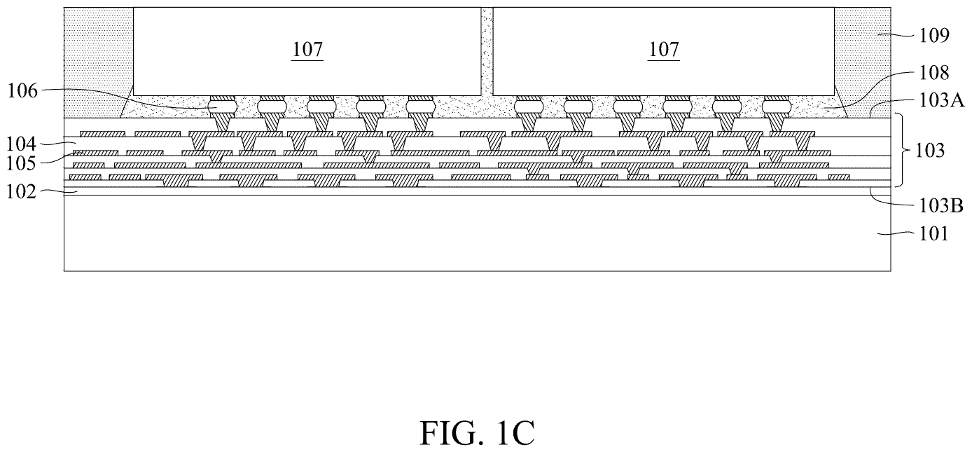

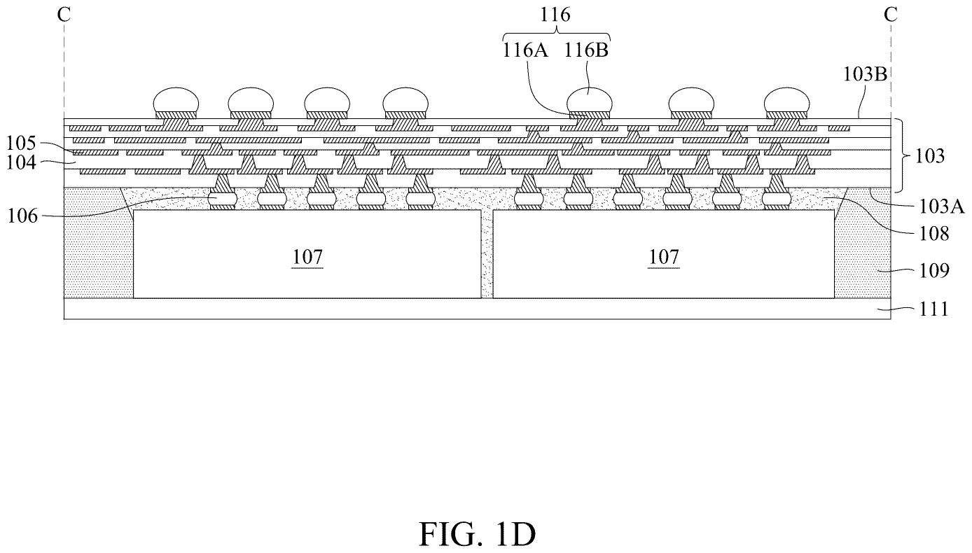

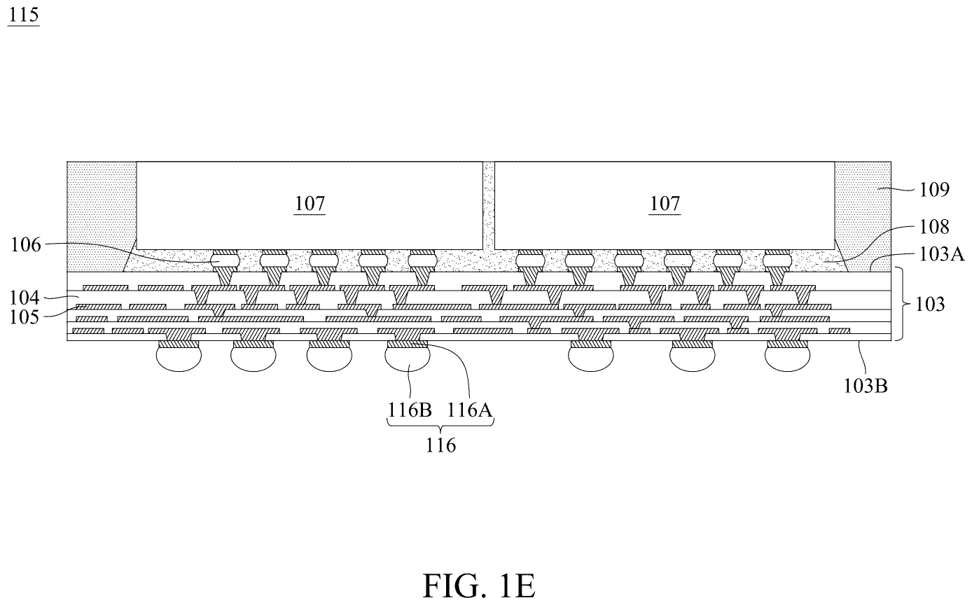

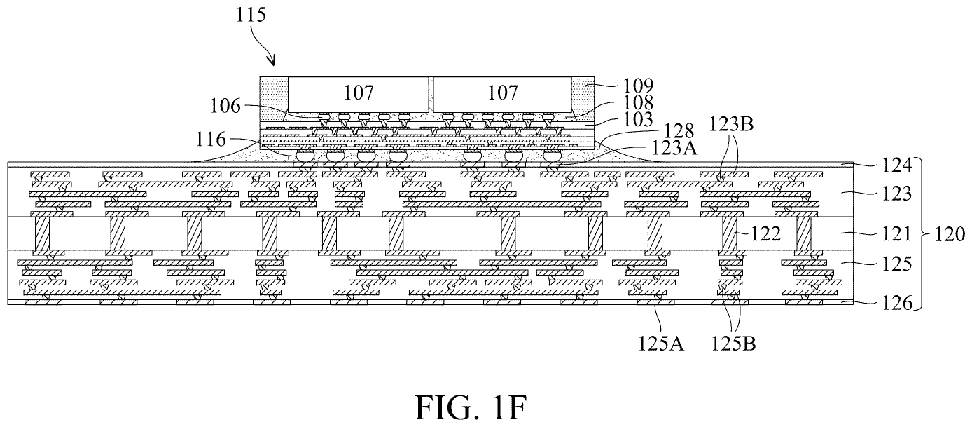

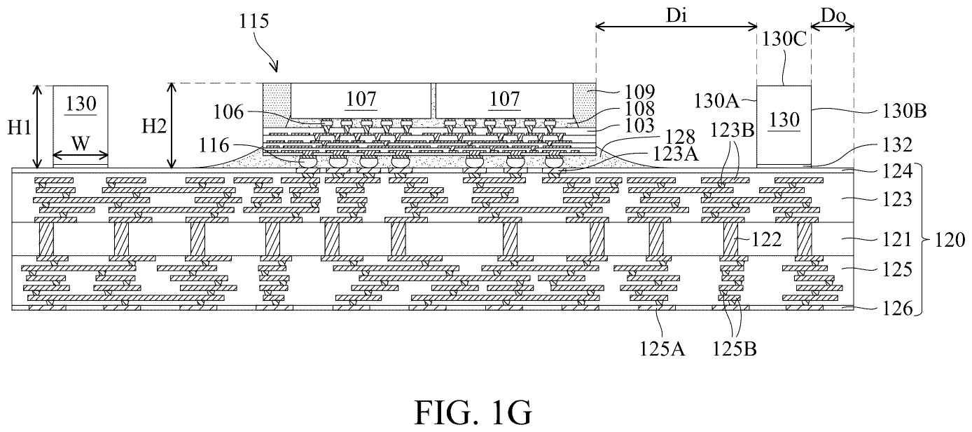

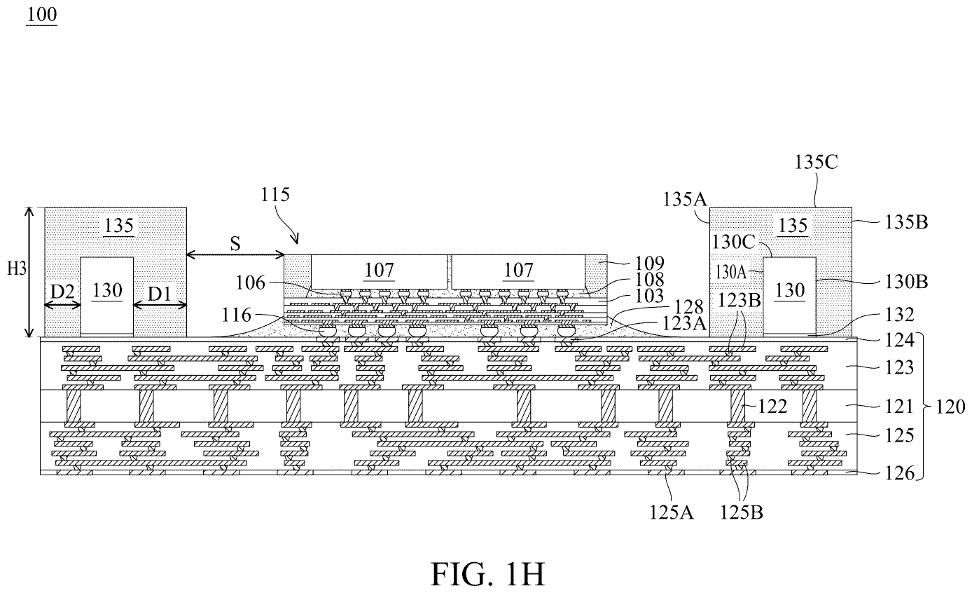

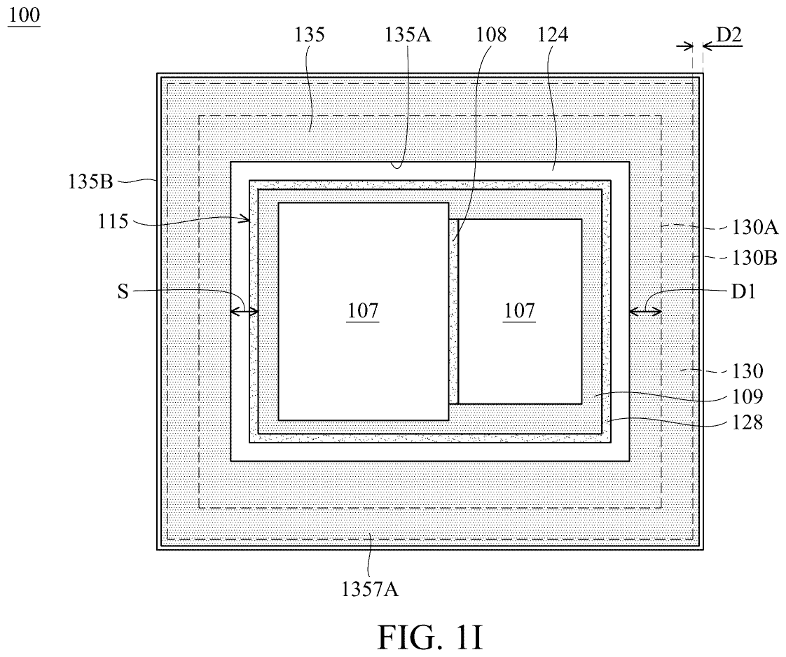

FIGS. 1A to 1I are schematic views of intermediate steps of forming a semiconductor package structure 100 (see FIGS. 1H and 1I) according to some embodiments of the present disclosure, wherein the semiconductor package structure 100 may be a Chip-on-Wafer-on-Substrate (CoWoS) package structure. It should be noted that the package structure (e.g., CoWoS package structure) discussed herein is merely an illustrative example, and the features of the embodiments described below may also be applied to other suitable package structures. Additional components or devices can also be added to the semiconductor package structure 100 in other embodiments. Some of the features described below can be replaced or eliminated for different embodiments.

FIG. 1A is a cross-sectional view of an intermediate structure during a process of forming the semiconductor package structure 100 according to some embodiments. Referring to FIG. 1A, the intermediate structure includes a carrier substrate 101 and an interposer 103 formed over a front side surface of the carrier substrate 101. The carrier substrate 101 may be configured to provide mechanical support to the interposer 103. The carrier substrate 101 may be formed of a suitable substrate material, such as a glass material, a ceramic material (e.g., a sapphire substrate), a semiconductor material (e.g., a silicon substrate), or the like. Other suitable materials for the carrier substrate 101 are within the contemplated scope of the disclosure.

In some embodiments, a release layer 102 may be formed over the front side surface of the carrier substrate 101, and the interposer 103 may be formed over the release layer 102. The release layer 102 may include an adhesive material that may adhere the interposer 103 to the front side surface of the carrier substrate 101. In some embodiments, the release layer 102 may be formed of a polymer-based material, which may be removed together with the carrier substrate 101 from the overlying structures that will be formed in subsequent steps. In some embodiments, the release layer 102 is an epoxy-based thermal-release material, which loses its adhesive property when heated, such as a light-to-heat-conversion (LTHC) release coating. In some embodiments, the release layer 102 may be an ultra-violet (UV) glue, which loses its adhesive property when exposed to UV light. The release layer 102 may be dispensed as a liquid and then cured, or it may be a laminate film laminated onto the carrier substrate 101, or the like. Other suitable materials for the release layer 102 are within the contemplated scope of the disclosure.

Referring again to FIG. 1A, the interposer 103 may include a first side surface 103A and a second side surface 103B opposite the first side surface 103A. The second side surface 103B may face the front side surface of the carrier substrate 101. A plurality of conductive interconnect structures 105 (e.g., metal lines and vias) may extend within the interposer 103 between the first side surface 103A and the second side surface 103B. The conductive interconnect structures 105 may be formed in and surrounded by an insulating matrix that may be composed of a dielectric material 104. The conductive interconnect structures 105 of the interposer 103 may be configured to route electrical signals between semiconductor IC dies and a package substrate in a semiconductor package structure to be subsequently formed.

In some embodiments, the interposer 103 may be an organic interposer. In one non-limiting example, the organic interposer 103 may be formed by sequentially depositing layers of dielectric material 104 (e.g., a dielectric polymer material) over the front side surface of the carrier substrate 101 (and over the release layer 102, if present). Each of the layers of dielectric material 104 may be lithographically patterned and etched to form open regions (e.g., trenches and/or via openings), and a metallization process may then be used to fill the open regions and form conductive interconnect structures 105 (e.g., metal lines and vias) within each successive layer of dielectric material 104. In this manner, the interposer 103 may be built layer-by-layer over the front side surface of the carrier substrate 101. In some embodiments, a plurality of bonding pads (not specifically marked) may also be formed in the uppermost and lowermost layers of dielectric material 104, and the bonding pads may be exposed on the first side surface 103A and the second side surface 103B of the interposer 103. Other details of the interposer 103 are not described here.

It should be noted that the structure of the interposer 103 shown in FIG. 1A is merely an illustrative example, and the present disclosure is not limited thereto. In addition, the interposer 103 may be in the form of a wafer and may include includes multiple identical die regions. For simplicity, only one die region of the interposer 103 is shown. In other embodiments, the organic interposer 103 can also be replaced with a silicon interposer. The details of a silicon interposer are not described here.

FIG. 1B is a cross-sectional view of the intermediate structure showing a plurality of semiconductor IC dies 107 mounted over the first side surface 103A of the interposer 103 within one die region according to some embodiments. Referring to FIG. 1B, in some embodiments, the semiconductor IC dies 107 may include at least one processor die, such as a system-on-chip (SoC) die, an application specific integrated circuit (ASIC) die, a central processing unit (CPU) die, and/or a graphic processing unit (GPU) die. In some embodiments, the semiconductor IC dies 107 may include at least one memory die, such as a high bandwidth memory (HBM) die and/or a dynamic random access memory (DRAM) die. In some embodiments, the semiconductor IC dies 107 may be homogeneous, meaning that all of the semiconductor IC dies 107 may be of the same type (e.g., all SoC dies, all HBM dies, all DRAM dies, etc.). Alternatively, the semiconductor IC dies 107 may be heterogeneous, meaning that the semiconductor IC dies 107 may include different types of semiconductor IC dies 107 (e.g., at least one processor die and at least one memory die). Although the embodiment of FIG. 1B illustrates two semiconductor IC dies 107 mounted over the interposer 103, a greater or lesser number of semiconductor IC dies 107 may be mounted to the interposer 103 in different embodiments.

Referring again to FIG. 1B, a plurality of bonding structures 106 may bond each of the semiconductor IC dies 107 to the first side surface 103A of the interposer 103. In various embodiments, the semiconductor IC dies 107 may be mounted over the first side surface 103A of the interposer 103 by placing each of the semiconductor IC dies 107 over the first side surface 103A of the interposer 103 (e.g., using a pick-and-place tool). The semiconductor IC dies 107 may be aligned over the first side surface 103A of the interposer 103 such that IC die bonding structures (e.g., metallic bumps, pillars, stacks, and/or bonding pads) on the lower surfaces of the semiconductor IC dies 107 contact corresponding interposer bonding structures (e.g., metallic bumps, pillars, stacks, and/or bonding pads) over the first side surface 103A of the interposer 103. A reflow process may then be used to bond the IC die bonding structures on the lower surfaces of the semiconductor IC dies 107 to the corresponding interposer bonding structures over the first side surface 103A of the interposer 103, thereby providing a mechanical and electrical connection between each of the semiconductor IC dies 107 and the interposer 103. In some embodiments, the semiconductor IC dies 107 may be bonded to the first side surface 103A of the interposer 103 using micro bump bonding (i.e., the bonding structures 106 may be micro bumps), although it should be understood that other bonding technologies and processes are within the contemplated scope of the disclosure.

Referring again to FIG. 1B, after bonding the semiconductor IC dies 107, an underfill material portion 108 may be filled into the spaces between the first side surface 103A of the interposer 103 and the semiconductor IC dies 107. The underfill material portion 108 may laterally surround and contact each of the bonding structures 106 that bond the respective semiconductor IC dies 107 to the interposer 103. The underfill material portion 108 may also be located between adjacent semiconductor IC dies 107 of the semiconductor IC dies 107 mounted to the interposer 103. The underfill material portion 108 may be made of or include an insulating material such as an underfill material. For example, the underfill material may include an epoxy, a resin, a filler material, a stress release agent (SRA), an adhesion promoter, another suitable material, or a combination thereof. In some embodiments, an underfill material in a liquid state is dispensed into the gaps between the first side surface 103A of the interposer 103 and the semiconductor IC dies 107, for example, in a capillary flow process, and then cured to form the underfill material portion 108.

FIG. 1C is a cross-sectional view of the intermediate structure showing a molding layer 109 laterally surrounding the underfill material portion 108 and the semiconductor IC dies 107 mounted over the interposer 103 according to some embodiments. Referring to FIG. 1C, the molding layer 109 may contact lateral side surfaces of at least some of the semiconductor IC dies 107 and may also contact the underfill material portion 108. The molding layer 109 may include an epoxy material. For example, the molding layer 109 may include an epoxy mold compound (EMC) that may include epoxy resin, a hardener (i.e., a curing agent), silica or other filler material(s), and optionally additional additives. The EMC may be applied around the periphery of the semiconductor IC dies 107 in liquid or solid form, and may be hardened (i.e., cured) to form a molding layer 109 having sufficient stiffness and mechanical strength surrounding the semiconductor IC dies 107. In some embodiments, portions of the molding layer 109 that extend above a horizontal plane including the top surfaces of the semiconductor IC dies 107 may be removed using a planarization process, such as a chemical mechanical planarization (CMP) process. In some embodiments, the planarization process may be omitted, for example, if the top surfaces of the semiconductor IC dies 107 are already exposed.

FIG. 1D is a cross-sectional view of the intermediate structure showing a tape layer 111 (e.g., a dicing tape) attached to the top surfaces of the semiconductor IC dies 107, the exposed top surface of the underfill material portion 108 and the exposed top surface of the molding layer 109, and then the intermediate structure is flipped upside down, according to some embodiments. FIG. 1D additionally shows the carrier substrate 101 removed from the intermediate structure to expose the second side surface 103B of the interposer 103. The carrier substrate 101 may be removed using any suitable method known in the art. In embodiments in which the carrier substrate 101 is adhered to the interposer 103 by a release layer 102, the release layer 102 may be subjected to optical or thermal treatments, causing the release layer 102 to lose its adhesive properties. This may enable the carrier substrate 101 to be separated from the exemplary intermediate structure.

Referring again to FIG. 1D, after the second side surface 103B of the interposer 103 is exposed, a plurality of bonding structures 116 may be formed to contact the exposed bonding pads at the second side surface 103B of the interposer 103 according to some embodiments. The bonding structures 116 (e.g., controlled collapse chip connection (C4) bumps) may be formed by forming metal pillars 116A (e.g., copper pillar) on the exposed bonding pads at the second side surface 103B of the interposer 103, for example, using an electroplating process. Solder bumps 116B may then be formed on the metal pillars 116A using a suitable process (e.g., deposition, electroplating, etc.). In some embodiments, underbump metallization (UBM) layers (not shown) may also be formed on the exposed bonding pads at the second side surface 103B of the interposer 103, and the metal pillars 116A of the C4 bumps 116 may be formed on the UBM layers. Other suitable bonding structures are within the contemplated scope of the disclosure.

Referring again to FIG. 1D, after the bonding structures 116 are formed, a singulation process (e.g., a saw process) may be performed along cutting grooves C, to form multiple separate, identical die package modules, according to some embodiments. Each of the die package modules may then be removed from the tape layer 111 using, for example, a pick-and-place tool (not shown). FIG. 1E is a cross-sectional view of the resulting structure in FIG. 1D (i.e., a die package module 115), the only difference is that the structure is flipped upside down. Referring to FIG. 1E, in some embodiments, the die package module 115 may include a plurality of semiconductor IC dies 107 mounted over the first side surface 103A of the interposer 103, a molding layer 109 encapsulating the semiconductor IC dies 107, and a plurality of C4 bumps 116 located on the second side surface 103B of the interposer 103. The die package module 115 may also sometimes be referred to as a “Chip-on-Wafer (CoW) device.”

FIG. 1F is a cross-sectional view of the intermediate structure in which the die package module 115 is attached to a package substrate 120 according to some embodiments. Referring to FIG. 1F, the package substrate 120 may include, for example, a substrate core 121, an upper redistribution structure 123 formed on the upper surface of the substrate core 121 (e.g., a first side or chip-side of the package substrate 120), and a lower redistribution layer 125 formed on the lower surface of the substrate core 121 (e.g., a second side or board-side of the package substrate 120). For example, the package substrate 120 may include a build-up film substrate such as an Ajinomoto build-up film (ABF) substrate according to some embodiments.

The substrate core 121 may help provide rigidity to the package substrate 120. The substrate core 121 may include, for example, an epoxy resin such as a bismaleimide triazine epoxy (BT epoxy) and/or a woven glass laminate. Alternatively or additionally, the substrate core 121 may include an organic material such as a polymer material. For example, the substrate core 121 may include a dielectric polymer material such as polyimide (PI), benzocyclo-butene (BCB), or polybenzobisoxazole (PBO). Other suitable dielectric materials are within the contemplated scope of the disclosure.

The substrate core 121 may include a plurality of through vias 122, which may extend from the lower surface of the substrate core 121 to the upper surface of the substrate core 121. The through vias 122 may allow an electrical connection between the upper redistribution layer 123 and the lower redistribution layer 125. The through vias 122 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of the disclosure.

The upper redistribution structure 123 may include a plurality of dielectric layers, and in particular may include an Ajinomoto build-up film (ABF). The upper redistribution structure 123 may also include an organic material such as a polymer material. For example, the upper redistribution structure 123 may include a dielectric polymer material such as polyimide (PI), benzocyclobutene (BCB), or polybenzobisoxazole (PBO). Other suitable dielectric materials are within the contemplated scope of the disclosure.

The upper redistribution structure 123 may include a plurality of upper bonding pads 123A located on (e.g., exposed on) a chip-side surface of the upper redistribution structure 123. The upper redistribution structure 123 may also include a plurality of conductive interconnect structures 123B that may be connected to the upper bonding pads 123A and the through vias 122 in the substrate core 121. The conductive interconnect structures 123B may include metal line layers and metal vias connecting the metal line layers. The upper bonding pads 123A and the conductive interconnect structures 123B may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of the disclosure.

An upper passivation layer 124 may be formed on the chip-side surface of the upper redistribution structure 123 and may partially cover the upper bonding pads 123A. The upper passivation layer 124 may include silicon oxide, silicon nitride, low-k dielectric materials such as carbon-doped oxides, extremely low-k dielectric materials such as porous carbon doped silicon dioxide, another suitable material, or a combination thereof.

The lower redistribution structure 125 may include a plurality of dielectric layers, and in particular may include an Ajinomoto build-up film (ABF). The lower redistribution structure 125 may also include an organic material such as a polymer material. For example, lower redistribution structure 125 may include a dielectric polymer material such as polyimide (PI), benzocyclobutene (BCB), or polybenzobisoxazole (PBO). Other suitable dielectric materials are within the contemplated scope of the disclosure.

The lower redistribution structure 125 may include a plurality of lower bonding pads 125A located on (e.g., exposed on) a board-side surface of the lower redistribution structure 125. The lower redistribution structure 125 may also include a plurality of conductive interconnect structures 125B that may be connected to the lower bonding pads 125A and the through vias 122 in the substrate core 121. The conductive interconnect structures 125B may include metal line layers and metal vias connecting the metal line layers. The lower bonding pads 125A and the conductive interconnect structures 125B may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of the disclosure.

A lower passivation layer 127 may be formed on the board-side surface of the lower redistribution structure 125 and may partially cover the lower bonding pads 125A. The lower passivation layer 127 may include silicon oxide, silicon nitride, low-k dielectric materials such as carbon-doped oxides, extremely low-k dielectric materials such as porous carbon doped silicon dioxide, another suitable material, or a combination thereof.

Referring again to FIG. 1F, in some embodiments, the die package module 115 may be attached to the package substrate 120, for example, using a flip chip bonding (FCB) process. In the FCB process, the die package module 115 may be positioned over the package substrate 120 using, for example, a pick-and-place tool (not shown). The C4 bumps 116 on the lower surface of the die package module 115 may be lowered onto the upper bonding pads 123A of the package substrate 120 and then heated in order to collapse the solder bump portion (e.g., 116B) of the C4 bumps 116 and bond the C4 bumps 116 to the upper bonding pads 123A.

Referring again to FIG. 1F, after bonding the die package module 115, a second underfill material portion 128 may be applied into the space between the lower surface of the die package module 115 and the chip-side surface (e.g., the surface of the upper passivation layer 124) of the package substrate 120. The second underfill material portion 128 may laterally surround and contact each of the C4 bumps 116 that bond the die package module 115 to the package substrate 120. The second underfill material portion 128 may further include a fillet portion extending beyond the periphery of the die package module 115 and onto the outer sidewall of the die package module 115 in some embodiments. The material and formation method of the second underfill material portion 128 may be similar to or the same as the material and formation method of the underfill material portion 108 described previously.

FIG. 1G is a cross-sectional view of the intermediate structure showing a stiffener ring 130 attached to the package substrate 120 according to some embodiments. Referring to FIG. 1G, the stiffener ring 130 may be attached to the chip-side surface (e.g., the surface of the upper passivation layer 124) of the package substrate 120 by an adhesive 132 (e.g., a silicone adhesive or an epoxy adhesive). The stiffener ring 130 may be formed of a metal such as copper with a nickel coating, or an aluminum alloy. Other suitable materials for the stiffener ring 130 are within the contemplated scope of the disclosure. The stiffener ring 130 may help provide rigidity to the package substrate 120 so as to reduce warpage and bending of the package substrate 120.

In some embodiments, the stiffener ring 130 may be attached to the package substrate 120 along the outer edges of the package substrate 120. For example, the stiffener ring 130 may have a rectangular or square ring shape in a plan view or a top view (e.g., see FIG. 1I, in which the stiffener ring 130 is depicted with dashed lines), depending on the shape of the package substrate 120. In some embodiments, the stiffener ring 30 may be located around the entire periphery of the die package module 115 and spaced apart from the die package module 115. The stiffener ring 30 may also be positioned to be laterally offset from the outer sidewall of the package substrate 120.

For example, the stiffener ring 130 may have an inner edge 130A and an outer edge 130B. The inner edge 130A of the stiffener ring 130 may be spaced apart from the outer sidewall of the die package module 115 by a certain distance Di, and the distance Di may be in arrange from about 1 mm to about 4 mm according to some embodiments. The outer edge 130B of the stiffener ring 130 may be spaced apart from the outer sidewall of the package substrate 120 by a certain distance Do, and the distance Do may be in arrange from about 0.5 mm to about 2 mm according to some embodiments. Other suitable distance ranges are also within the contemplated scope of the disclosure.

Since the various components and substrate materials used in the package structure may have different coefficients of thermal expansions (CTE) (e.g., the CTE of the silicon dies (e.g., 107) of the die package module 115 may be about 3 to 4 ppm/°C, while the CTE of the package substrate 120 may be about 11 to 20 ppm/°C), when the package structure undergoes thermal cycling during package assembly, reliability testing, or field operation, the components and substrate materials may expand at different rates, causing the package substrate 120 to warp, with the package substrate 120 typically bowing into a convex shape. It should be understood that, although the stiffener ring 130 can reduce this warpage to some extent, since the stiffener ring 130 constrains the package substrate 120, this constraining force also generates stress in the package substrate 120 and the die package module 115 connected to the package substrate 120, which may cause some problems such as cracks or delamination of the underfill material portions (e.g., 108, 208) in the package structure.

In some embodiments, the above internal stress issues may be reduced by reducing the size (e.g., the height and/or the width) of the stiffener ring 130. For example, in some embodiments, the height H1 of the stiffener ring 130 (measured from the top surface 130C of the stiffener ring 130 to the chip-side surface of the package substrate 120) may be reduced to be equal to or less than the height H2 of the die package module 115 (measured from the top surface of the die package module 115 to the chip-side surface of the package substrate 120) so as to reduce the above internal stress issues caused by the larger modulus of the stiffener ring 130. However, it has been found that this approach of reducing the size of the stiffener ring will also lead to worse substrate warpage. In this regard, the present disclosure introduces a stiffener mold to reduce both the substrate warpage and internal stress issues, which will be described below.

FIGS. 1H and 1I are a cross-sectional view and a plan view (e.g., top view), respectively, of the intermediate structure showing a stiffener mold 135 covering the stiffener ring 130 according to some embodiments. Referring to FIGS. 1H and 1I, the stiffener mold 135 may be formed over (e.g., in contact with) the chip-side surface of the package substrate 120 along the outer edges of the package substrate 120 and may cover (e.g., in contact with) the stiffener ring 130. In some embodiments, the stiffener mold 135 may be formed by a molding process such as injection molding, transfer molding, compression molding or over-molding.

In some embodiments, the molding material of the stiffener mold 135 includes a resin such as an epoxy resin, a phenolic resin or a thermosetting resin material. In some embodiments, the material of the stiffener mold 135 may be similar to or the same as the material of the molding layer 109 described previously. In some embodiments, the stiffener mold 135 is made of a molding material having a CTE greater than the CTE of the stiffener ring 130 (e.g., about 10 to 16 ppm/°C) and/or greater than the CTE of the package substrate 120 (about 11 to 20 ppm/°C). For example, the CTE of the stiffener mold 135 is greater than 20 ppm/°C, greater than 25 ppm/°C, or even greater in some cases.

By disposing a stiffener mold 135 with a larger CTE to cover the stiffener ring 130 over the package substrate 120, the warpage of the package substrate 120 can be balanced (even if a smaller stiffener ring 130 is used), thereby improving package warpage control. Further, due to the presence of the stiffener mold 135, a smaller stiffener ring 130 can also be used (for example, the height H1 of the stiffener ring 130 may be about half of the height H2 of the die package module 115, and/or the width W of the stiffener ring 130 may be reduced by half or more in some cases), which helps reduce internal stress issues caused by the larger modulus of the stiffener ring 130. Accordingly, the combination of the stiffener ring 130 and the stiffener mold 135 (which may be collectively referred to as a “stiffener structure”) reduces both the substrate warpage and internal stress issues.

Referring again to FIGS. 1H and 1I, in some embodiments, the stiffener mold 135 may cover all outer surfaces (including the inner edge 130A, the outer edge 130B and the top surface 130C) of the stiffener ring 130, so that the stiffener ring 130 is embedded in the stiffener mold 135 and is not exposed. In some embodiments, the stiffener mold 135 may have a rectangular or square ring shape in a plan view, corresponding to the shape of the stiffener ring 130. In some embodiments, the stiffener mold 135 may be located around the entire periphery of the die package module 115 and spaced apart from the die package module 115.

For example, the stiffener mold 135 may have an inner edge 135A (adjacent to the inner edge 130A of the stiffener ring 130) and an outer edge 135B (adjacent to the outer edge 130B of the stiffener ring 130). The inner edge 135A of the stiffener mold 135 may be spaced apart from the outer sidewall of the die package module 115 by a certain distance S (i.e., they are not in contact). In some embodiments, the distance S may be sufficient (e.g., larger than 1.5 mm) to allow an optional heat sink (not shown) to be placed above the die package module 115 through an opening between the opposite inner sidewalls of the stiffener mold 135. In some embodiments, the inner edge 135A of the stiffener mold 135 may also be spaced apart from the outer surface of the underfill material portion 128 (i.e., they are not in contact). This design can prevent additional stress on the die package module 115 and additional interface delamination issues (e.g., at the interface between the stiffener mold 135 and the molding layer 109 of the die package module 115 and/or at the interface between the stiffener mold 135 and the underfill material portion 128), thereby improving the reliability of the package structure.

In some embodiments, the inner edge 135A of the stiffener mold 135 is spaced apart from the inner edge 130A of the stiffener ring 130 by a certain distance D1, and the outer edge 135B of the stiffener mold 135 is spaced apart from the outer edge 130B of the stiffener ring 130 by a certain distance D2, wherein the distances D1 and D2 may be sufficient (e.g., larger than 0.3 mm) to enhance the mechanical strength of the stiffener mold 135. In some embodiments, the distance D1 may be greater than the distance D2, but the present disclosure is not limited thereto. In some embodiments, the top surface 135C of the stiffener mold 135 is flat or planar, and the height H3 of the stiffener mold 135 (measured from the top surface 135C of the stiffener mold 135 to the chip-side surface of the package substrate 120) may be greater than the height H1 of the stiffener ring 130 and greater than the height H2 of the die package module 115. The height H3 of the stiffener mold 135 may be in a range of about 3 mm to about 6 mm, although other suitable height ranges may be used.

Referring again to FIG. 1H, in some embodiments, after the stiffener mold 135 is formed, a plurality of solder balls (not shown for simplicity) may be formed on the lower bonding pads 125A of the package substrate 120. The solder balls may be formed, for example, using an electroplating process. The solder balls may constitute a ball-grid array (BGA) that may allow the package substrate 120 to be mounted (e.g., by surface mount technology (SMT)) on a substrate such as a printed circuit board (PCB) and electrically coupled to the substrate. After the solder balls are formed, the formation of the semiconductor package structure 100 (e.g., CoWoS package structure) is complete.

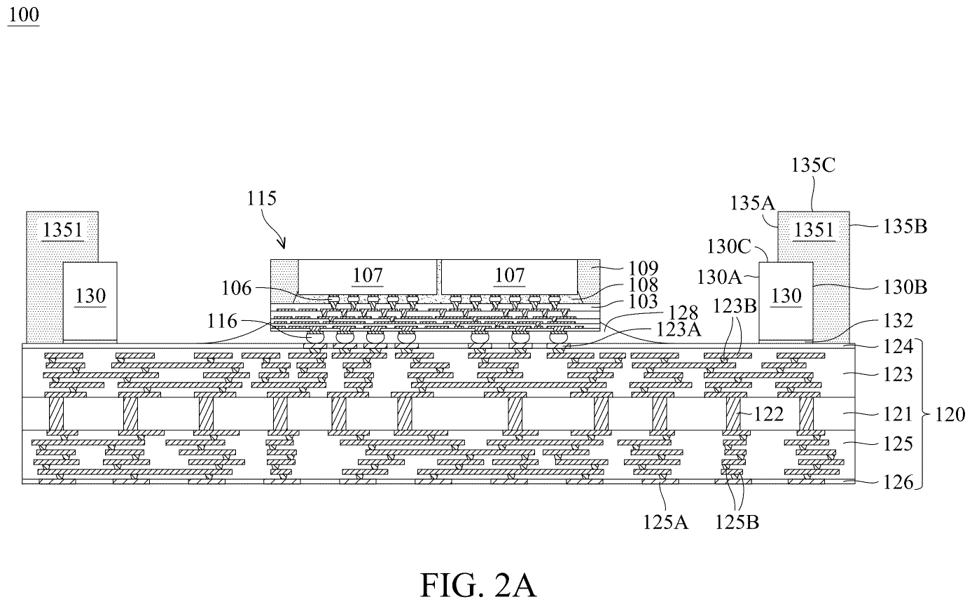

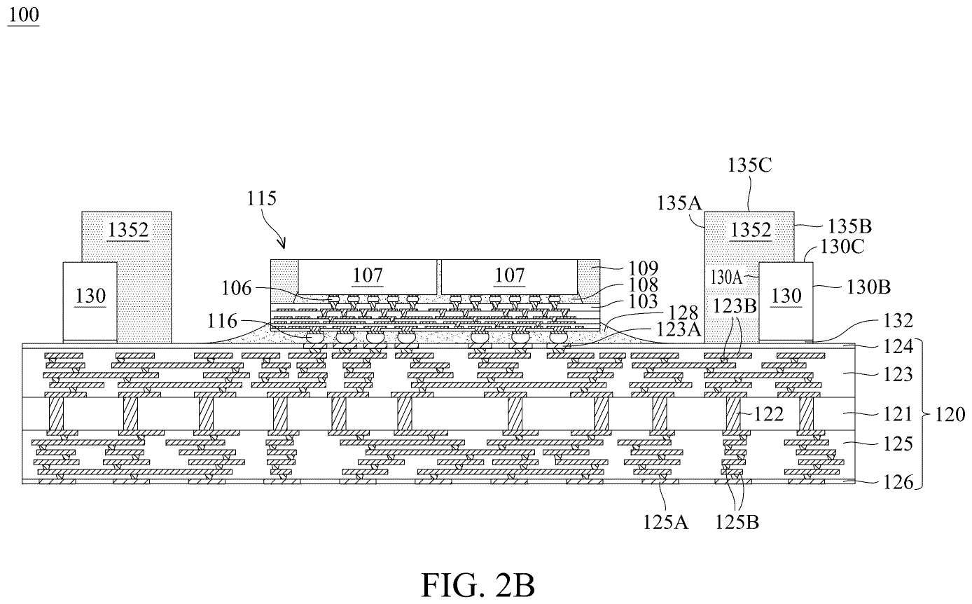

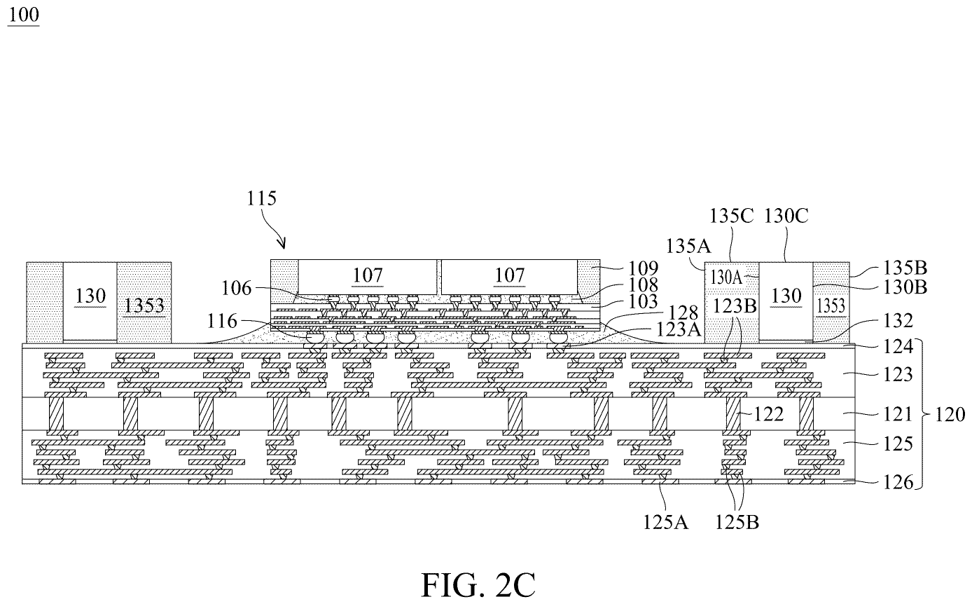

Many variations and/or modifications can be made to embodiments of the disclosure. Some variations of some embodiments are described below with reference to FIGS. 2A to 6. It should be noted that the following discussion describes only those features (e.g., with respect to the stiffener mold) that differ from the embodiments of FIGS. 1A to 1I.

FIGS. 2A to 2C illustrate cross-sectional views of semiconductor package structures 100 having stiffener molds (1351, 1352, 1353) with different configurations (e.g., only partially covering the stiffener ring 130) according to some embodiments. Referring to FIG. 2A, in some embodiments, the stiffener mold 1351 may cover the outer edge 130B of the stiffener ring 130 and may also cover at least a portion of the top surface 130C of the stiffener ring 130 so that the inner edge 130A of the stiffener ring 130 is exposed. Referring to FIG. 2B, the stiffener mold 1352 may cover the inner edge 130A of the stiffener ring 130 and may also cover at least a portion of the top surface 130C of the stiffener ring 130 so that the outer edge 130B of the stiffener ring 130 is exposed. Referring to FIG. 2C, the stiffener mold 1353 may laterally cover the inner edge 130A and the outer edge 130B of the stiffener ring 130 so that the top surface 130C of the stiffener ring 130 is exposed. It should be understood that the stiffener molds of these configurations (e.g., covering only some outer surfaces of the stiffener ring 130) can also achieve similar effects to the stiffener mold 135 in the embodiments of FIGS. 1A to 1I.

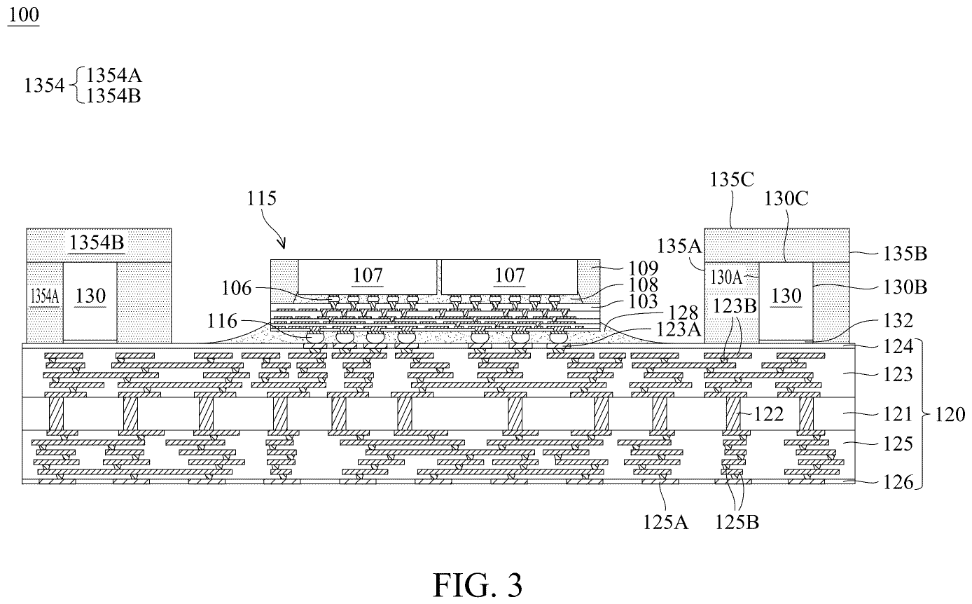

FIG. 3 illustrate a cross-sectional view of a semiconductor package structure 100 having a stiffener mold 1354 composed of a plurality of sub-molds (1354A, 1354B) according to some embodiments. Referring to FIG. 3, in some embodiments, the stiffener mold 1354 may include a first sub-mold 1354A located over (e.g., in contact with) the chip-side surface of the package substrate 120 and a second sub-mold 1354B located over the first sub-mold 1354A. The first sub-mold 1354A and the second sub-mold 1354B may have the same width and aligned sidewalls, but the present disclosure is not limited thereto. In some embodiments, the first sub-mold 1354A may laterally cover the inner edge 130A and the outer edge 130B of the stiffener ring 130 so that the top surface 130C of the stiffener ring 130 is exposed (i.e., the height of the first sub-mold 1354A is equal to or less than the height of the stiffener ring 130). In other embodiments, the first sub-mold 1354A may also cover the top surface 130C of the stiffener ring 130 so that the stiffener ring 130 is embedded in the first sub-mold 1354A (i.e., the height of the first sub-mold 1354A is greater than the height of the stiffener ring 130).

In various embodiments, the CTE of the first sub-mold 1354A may be greater than the CTE of the stiffener ring 130, and the CTE of the second sub-mold 1354B may be greater than the CTE of the first sub-mold 1354A. This design increases the CTE of the entire stiffener mold 1354, thereby improving package warpage control. In some embodiments, the CTE of the first sub-mold 1354A may be substantially equal to (e.g., equal to or slightly greater than) the CTE of the package substrate 120, which reduces or avoids the chance of delamination at the interface of the first sub-mold 1354A and the package substrate 120. In some embodiments, the first sub-mold 1354A and the second sub-mold 1354B may be formed using two molding processes. In other embodiments, the stiffener mold may include more than two sub-molds wherein the uppermost sub-mold has a larger CTE than the lower sub-molds.

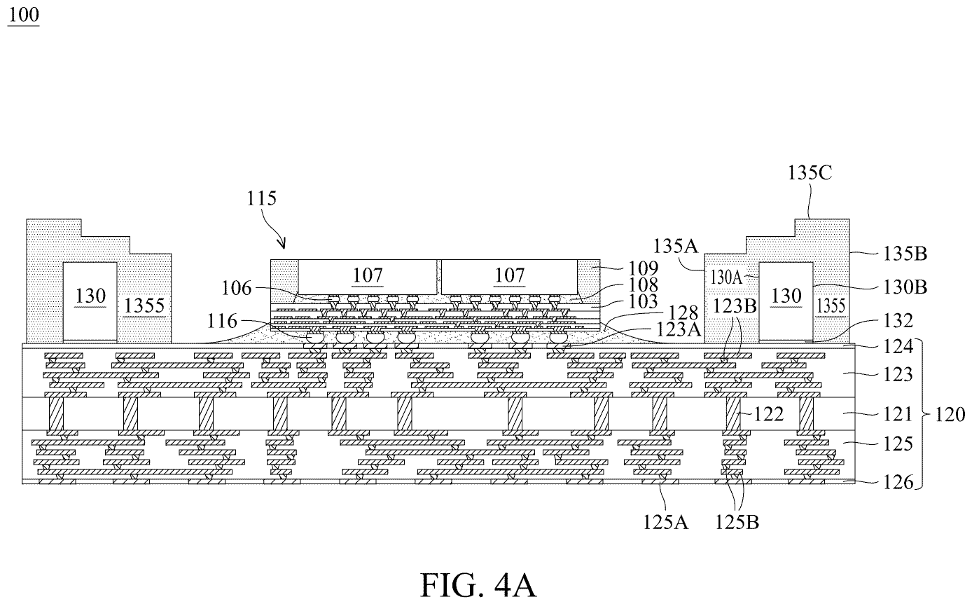

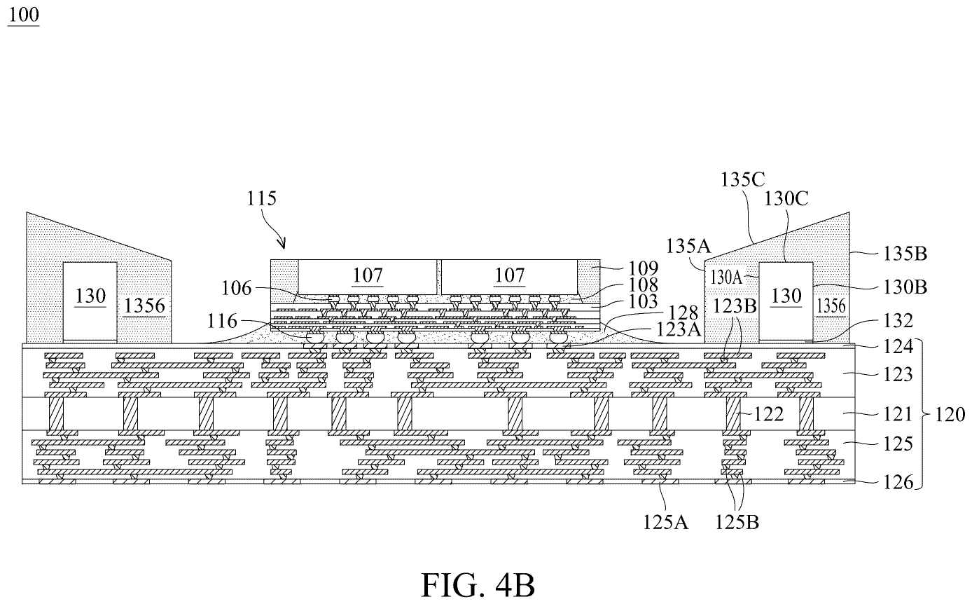

FIGS. 4A and 4B illustrate cross-sectional views of semiconductor package structures 100 having stiffener molds (1355, 1356) with uneven thickness (e.g., the thickness or height of the portion near the outer edge 135B is greater than the thickness or height of the portion near the inner edge 135A) according to some embodiments. It should be understood that the package substrate 120 generally has a larger amount of bending at the edges. Therefore, the thicker outer portion of the stiffener mold may help balance or reduce the warpage of the package substrate 120, thereby improving the flatness of the package substrate 120. Referring to FIG. 4A, the top surface 135C of the stiffener mold 1355 has a stepped shape (e.g., three steps) in a cross-sectional view. In general, forming more steps on the top surface 135C (especially directly above the stiffener ring 130) helps improve warpage control. Other numbers of the steps may be used in different embodiments. Referring to FIG. 4B, the top surface 135C of the stiffener mold 1356 has a slope shape in a cross-sectional view. Other suitable cross-sectional shapes for the top surface 135C of the stiffener mold are within the contemplated scope of the disclosure.

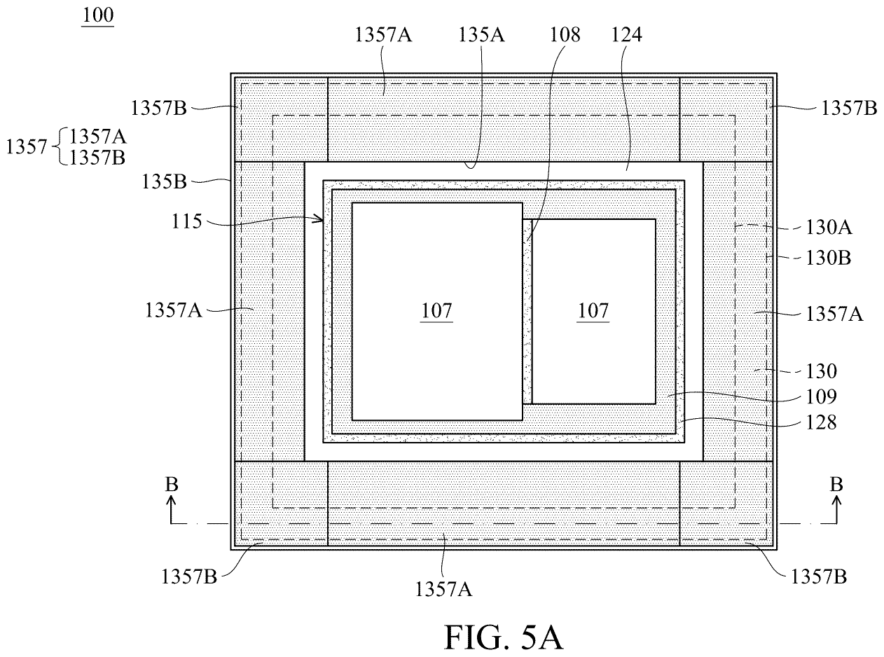

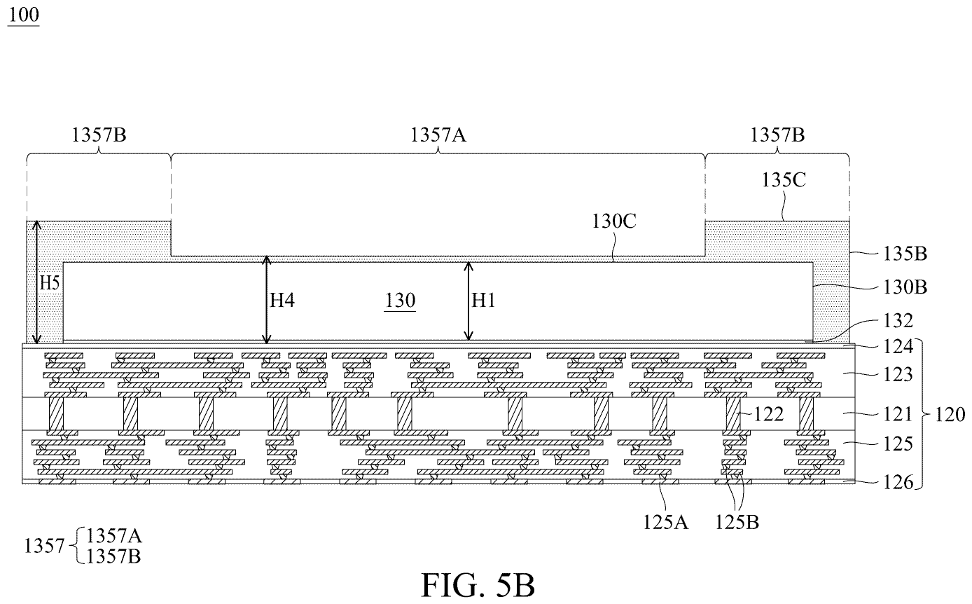

FIG. 5A is a plan view of a semiconductor package structure 100 having a stiffener mold 1357 with uneven thickness according to some embodiments. FIG. 5B is a cross-sectional view taken along line B-B shown in FIG. 5A. Referring to FIGS. 5A and 5B, the stiffener mold 1357 may include a plurality of (e.g., four (4)) side portions 1357A and a plurality of (e.g., four (4)) corner portions 1357B, wherein any two adjacent corner portions 1357B are separated by one side portion 1357 and vice versa. The side portions 1357A and the corner portions 1357B together may form a complete ring-shaped stiffener mold 1357 in a plan view. In some embodiments, each of the side portions 1357A and the corner portions 1357B of the stiffener mold 1357 may cover all outer surfaces (including the inner edge 130A, the outer edge 130B and the top surface 130C) of the stiffener ring 130 in a cross-sectional view, but the present disclosure is not limited thereto. In various embodiments, the thickness or height H4 of the side portions 1357A may be smaller than the thickness or height H5 of the corner portions 1357B (i.e., the corner portions 1357B are thicker than the rest), and the thickness or height H4 of the side portions 1357A may be greater than the thickness or height H1 of the stiffener ring 130. It should be understood that the package substrate 120 generally has a greatest amount of bending at the corners. Therefore, the thicker corner portions of the stiffener mold may help balance or reduce the warpage of the package substrate 120, thereby improving the flatness of the package substrate 120.

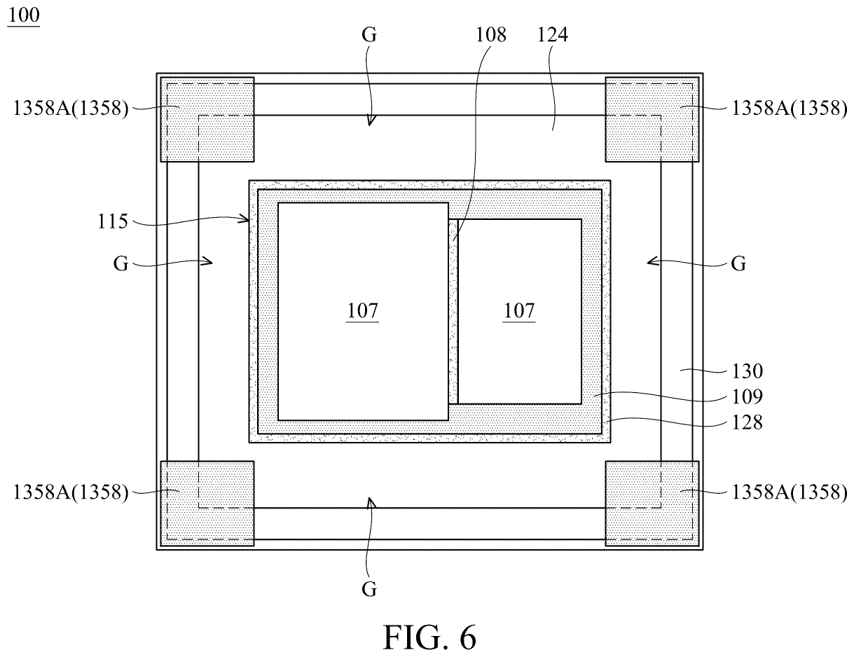

FIG. 6 illustrate a plan view of a semiconductor package structure 100 having a stiffener mold 1358 covering only the corner areas of the stiffener ring 130 according to some embodiments. As shown in FIG. 6, the stiffener mold 1358 may include a plurality of (e.g., four (4)) molding parts 1358A separated from each other, wherein the molding parts 1358A are positioned corresponding to the corner areas of the stiffener ring 130 (and the corners of the package substrate 120). The side areas of the stiffener ring 130 may be exposed through openings G between the molding parts 1358A. In some embodiments, each of the molding parts 1358A may cover all outer surfaces (including the inner edge 130A, the outer edge 130B and the top surface 130C) of the stiffener ring 130 at the corresponding corner area in a cross-sectional view, but the present disclosure is not limited thereto. It should be understood that this design of the stiffener mold 1358 can also achieve similar effects to the stiffener mold 1357 in the embodiments of FIGS. 5A and 5B.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, various features in the above-mentioned different embodiments can be combined arbitrarily. In addition, while the present disclosure is described using embodiments in which a die package module is surrounded by a stiffener structure above a package substrate, embodiments in which a semiconductor chip or device is surrounded by a stiffener structure above a package substrate are expressly contemplated herein.

In summary, the embodiments of the present disclosure have some advantageous features. By disposing a stiffener mold with a larger CTE to cover the stiffener ring on the package substrate, the warpage of the package substrate can be balanced, thereby improving package warpage control. Further, due to the presence of the stiffener mold, a smaller stiffener ring can also be used, which helps reduce internal stress issues caused by the larger modulus of the stiffener ring. Additionally, the stiffener mold is spaced apart from the semiconductor device (e.g., die package module) (i.e., they are not in contact), thereby preventing additional stress on the semiconductor device and additional interface delamination issues. Accordingly, the reliability of the package structure is improved.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments, a semiconductor package structure is provided. The semiconductor package structure includes a package substrate, a semiconductor device, a stiffener ring, and a stiffener mold. The semiconductor device is mounted over the package substrate. The stiffener ring is attached to the package substrate and surrounds the semiconductor device. The stiffener mold is formed over the package substrate and covers the stiffener ring. The coefficient of thermal expansion (CTE) of the stiffener mold is greater than the CTE of the stiffener ring. In addition, the stiffener mold is spaced apart from the semiconductor device.

In accordance with some embodiments, a semiconductor package structure is provided. The semiconductor package structure includes a package substrate, a semiconductor device, a stiffener ring, and a stiffener mold. The semiconductor device is mounted over the package substrate. The stiffener ring is attached to the package substrate and surrounds the semiconductor device. The stiffener mold is formed over the package substrate along all outer edges of the package substrate and covers the stiffener ring. The stiffener mold has a ring shape corresponding to the stiffener ring and is spaced apart from the semiconductor device in a plan view.

In accordance with some embodiments, a method of forming a semiconductor package structure is provided. The method includes mounting a semiconductor device over a package substrate. The method also includes attaching a stiffener ring to the package substrate to surround the semiconductor device. The method also includes forming a stiffener mold over the package substrate so that the stiffener mold covers the stiffener ring and is spaced apart from the semiconductor device. The coefficient of thermal expansion (CTE) of the stiffener mold is greater than the CTE of the stiffener ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a package substrate;
a semiconductor device mounted over the package substrate;
a stiffener ring attached to the package substrate and surrounding the semiconductor device; and
a stiffener mold formed over the package substrate and covering the stiffener ring, wherein a coefficient of thermal expansion (CTE) of the stiffener mold is greater than a CTE of the stiffener ring, and the stiffener mold is spaced apart from the semiconductor device.

2. The semiconductor package structure as claimed in claim 1, wherein the CTE of the stiffener mold is greater than a CTE of the package substrate.

3. The semiconductor package structure as claimed in claim 1, wherein the semiconductor device is mounted on the package substrate through a plurality of bonding structures, and the semiconductor package structure further comprises:
an underfill material portion laterally surrounding the bonding structures, wherein the stiffener mold is spaced apart from the underfill material portion.

4. The semiconductor package structure as claimed in claim 1, wherein a height of stiffener ring is equal to or less than a height of the semiconductor device.

5. The semiconductor package structure as claimed in claim 1, wherein the stiffener mold covers all outer surfaces of the stiffener ring.

6. The semiconductor package structure as claimed in claim 1, wherein the stiffener mold partially covers the stiffener ring and exposes some outer surfaces of the stiffener ring.

7. The semiconductor package structure as claimed in claim 1, wherein the stiffener mold includes a first sub-mold and a second sub-mold located over the first sub-mold, and a CTE of the second sub-mold is greater than a CTE of the first sub-mold.

8. The semiconductor package structure as claimed in claim 1, wherein the stiffener mold has an inner edge facing the semiconductor device and an outer edge opposite the inner edge, and a height of a portion of the stiffener mold near the outer edge is greater than a height of a portion of the stiffener mold near the inner edge.

9. The semiconductor package structure as claimed in claim 1, wherein the stiffener mold is formed over the package substrate along all outer edges of the package substrate, and the stiffener mold includes a plurality of corner portions located corresponding to corners of the package substrate and a plurality of side portions between the corner portions, wherein the corner portions are thicker than the side portions.

10. The semiconductor package structure as claimed in claim 1, wherein the stiffener mold is formed over the package substrate and covering only corner areas of the stiffener ring.

11. A semiconductor package structure, comprising:
a package substrate;
a semiconductor device mounted over the package substrate;
a stiffener ring attached to the package substrate and surrounding the semiconductor device; and
a stiffener mold formed over the package substrate along all outer edges of the package substrate and covering the stiffener ring, wherein the stiffener mold has a ring shape corresponding to the stiffener ring and is spaced apart from the semiconductor device in a plan view.

12. The semiconductor package structure as claimed in claim 11, wherein a coefficient of thermal expansion (CTE) of the stiffener mold is greater than a CTE of the stiffener ring.

13. The semiconductor package structure as claimed in claim 11, wherein the stiffener mold overlaps the stiffener ring in the plan view.

14. The semiconductor package structure as claimed in claim 11, wherein the stiffener mold partially overlaps the stiffener ring in the plan view, and an inner edge or an outer edge of the stiffener ring is exposed.

15. The semiconductor package structure as claimed in claim 11, wherein the stiffener mold surrounds an inner edge and an outer edge of the stiffener ring in the plan view.

16. The semiconductor package structure as claimed in claim 15, wherein a top surface of the stiffener ring is exposed from the stiffener mold.

17. The semiconductor package structure as claimed in claim 11, wherein the stiffener mold has an inner edge facing the semiconductor device and an outer edge opposite the inner edge, and a height of a portion of the stiffener mold near the outer edge is greater than a height of a portion of the stiffener mold near the inner edge.

18. A method of forming a semiconductor package structure, comprising:
mounting a semiconductor device over a package substrate;
attaching a stiffener ring to the package substrate to surround the semiconductor device; and
forming a stiffener mold over the package substrate so that the stiffener mold covers the stiffener ring and is spaced apart from the semiconductor device, wherein a coefficient of thermal expansion (CTE) of the stiffener mold is greater than a CTE of the stiffener ring.

19. The method as claimed in claim 18, wherein the stiffener mold is formed over the package substrate along all outer edges of the package substrate and has a ring shape corresponding to the stiffener ring.

20. The method as claimed in claim 18, wherein the stiffener mold is formed over the package substrate to cover only corner areas of the stiffener ring.
